(19) United States
(12) Patent Application Publication
(10) Pub. No.: US 2020/0051717 A1
(43) Pub. Date: Feb. 13, 2020

(54) CURRENT SENSING RESISTOR

(71) Applicant: KOA CORPORATION, Ina-shi, Nagano (JP)

(72) Inventors: KEISHI NAKAMURA, Nagano (JP); Kenichi IGUCH!, Nagano (JP); Susumu TOYODA, Nagano (JP); Sonho TODO, Nagano (JP)

(21) Appl. No.: 16/497,220

(22) PCT Filed: Feb. 28, 2018
(86) PCT No.: PCT/JP2018/007395

§ 371 Date: Sep. 24, 2019

(30) Foreign Application Priority Data
Mar. 30, 2017 (JP) 2017-068955

(51) Int. Cl. H01C 1/14; H01L 25/16; H01L 23/495; H01L 23/64; H01C 1/01; G01R 1/20

(52) U.S. Cl. CPC H01C 1/14; H01L 25/16; G01R 1/203; H01L 23/647; H01C 1/01; H01L 23/4952

(57) ABSTRACT

A current sensing resistor including: a first terminal and a second terminal which are made from an electrically conductive metal material; and a resistive element disposed between the first terminal and the second terminal. The resistive element, the first terminal, and the second terminal constitute a laminate in a thickness direction. The laminate has a size less than or equal to 5 mm.

### RELATED APPLICATIONS

This application is a 371 application of PCT/JP2018/007395 having an international filing date of Feb. 28, 2018, which claims priority to JP2017-068955 filed Mar. 30, 2017, the entire content of each of which is incorporated herein by reference.

### TECHNICAL FIELD

The present invention relates to a current sensing resistor and a current sensing device that are preferable for use in sensing current in a power semiconductor and the like.

### BACKGROUND ART

FIGS. 10A and 10B depict a perspective view and a cross sectional view, respectively, which illustrate a configuration example of a conventional shunt resistor. A first terminal 1 and a second terminal 3 are bonded to both ends of a planar resistive element 5. The first terminal 1 and the second terminal 3 are raised structures having a height difference. The shunt resistor has a self-inductance value that increases in proportion to the length of the resistive element 5.

In recent years, in response to increases in currents being used in electronic apparatuses, there has been much development in modules called power modules for converting or controlling electric power by switching performed by power semiconductors. In power modules, there has been an increasing use of high heat-dissipation substrates allowing for large current flows, such as a ceramic substrate called a DBC substrate formed by bonding copper directly onto an alumina substrate. Components such as a power semiconductor and a shunt resistor may be installed and used directly on a plate-like wiring member (lead frame) made of a copper plate or the like.

Patent Literature 1 below discloses a mount structure of a current sensing resistor.

As power semiconductors, SiC and GaN elements have been developed. These elements raise the available temperature range, making switching at high frequencies possible.

In Patent Literature 1, a resistive metal element is sandwiched between current terminals to constitute a current sensing shunt resistor. In this way, it is possible to obtain a current sensing shunt resistor that has good heat dissipation and high reliability.

### CITATION LIST

### Patent Literature

Patent Literature 1: JP 2001-358283 A

### SUMMARY OF INVENTION

### Technical Problem

In Patent Literature 1, the purpose of the current sensing shunt resistor is to improve heat dissipation and reliability and to decrease wiring length. It is expected that, in the future, the current sensing shunt resistor will be increasingly required to meet the following performance needs. First, there will be a need for a structure that can be directly attached to a DBC substrate or a plate-like wiring member, and that can suppress cracking due to a heat cycle. Accordingly, there will be a need for a structure with which it is possible to ensure conduction using wire bonding and the like. Sensing of large currents will also become necessary. Thus, lower resistance values of the shunt resistor will be needed. Further, in view of expected use in high frequencies of 20 kHz or above, a structure for minimizing self-inductance will be needed. In addition, in order to reduce the size of apparatus, minimizing the footprint of components such as a shunt resistor will be needed.

An object of the present invention is to provide a shunt resistor structure and a current sensing device that are preferable for use in a power module and the like, are small-sized, and have small inductance.\

### Solution to Problem

The present invention provides a shunt resistor structure in which electrodes and a resistive element are laminated. The electrodes are suitable for connection by wire bonding, a vertical current path with respect to a substrate or the like for mounting is obtained, and the footprint can be reduced, making it possible to reduce self-inductance value.

According to an aspect of the present invention, there is provided a current sensing resistor including: a first terminal and a second terminal which are made from an electrically conductive metal material; and a resistive element disposed between the first terminal and the second terminal. The resistive element, the first terminal, and the second terminal constitute a laminate in a thickness direction. The laminate has a size of less than or equal to 5 mm. Preferably, the laminate has a thickness of less than or equal to 0.5 mm. Also preferably, each of the first terminal and the second terminal has a thickness smaller than a thickness of the resistive element.

An insulating material may be provided on an outer periphery of the laminate. Preferably, a metal thin-film layer is provided on a surface of at least one of the first terminal and the second terminal in the thickness direction of the laminate.

The first terminal and the second terminal may have different areas. The first terminal may have a ring shape with a through-hole.

The present invention also provides a current sensing device including: a semiconductor element having a pair of main electrodes; and a current sensing resistor disposed on the semiconductor element, and including a first terminal and a second terminal which are made from an electrically conductive metal material, and a resistive element disposed between the first terminal and the second terminal. The resistive element, the first terminal, and the second terminal constitute a laminate in a thickness direction. The first terminal or the second terminal of the current sensing resistor is connected to at least one of the main electrodes.

The present invention also provides a current sensing device including: a current sensing resistor including a first terminal and a second terminal which are made from an electrically conductive metal material, and a resistive element disposed between the first terminal and the second terminal, wherein the resistive element, the first terminal, and the second terminal constitute a laminate in a thickness direction, and the laminate has a size of less than or equal to 5 mm; and a wiring member on which the current sensing resistor is mounted. The second terminal of the current sensing resistor is connected to the wiring member.

In the foregoing, preferably a different wiring member is provided, and the different wiring member and the first terminal are connected by a wire.

The description includes the contents disclosed in JP Patent Application No. 2017-068955 from which the present application claims priority.

### Advantageous Effects of Invention

According to the present invention, it is possible to provide a shunt resistor structure which is very small and low-profile and has excellent mounting properties and good high frequency characteristics.

### BRIEF DESCRIPTION OF DRAWINGS

FIGS. 1A, 1B and 1C depict a configuration example of a current sensing resistor according to a first embodiment of the present invention. FIG. 1A is a perspective view, and FIG. 1C is a cross sectional view. FIG. 1B is a perspective view illustrating a configuration example of a current sensing resistor according to a second embodiment of the present invention.

FIGS. 2A, 2B, 2C and 2D illustrate an example of a method of manufacturing a current sensing resistor according to the first embodiment of the present invention. FIGS. 2E and 2F show a modification thereof and illustrating an example of a method of manufacturing a current sensing resistor according to a second embodiment.

FIGS. 3A, 3B and 3C depict an example of a mounting structure for mounting the current sensing resistor according to the first embodiment of the present invention onto a substrate.

FIGS. 4A and 4B depict a configuration example of a current sensing resistor according to a third embodiment of the present invention. FIG. 4A is a perspective view, and FIG. 4B is a cross sectional view.

FIGS. 5A, 5B and 5C depict a configuration example of a current sensing resistor according to a fourth embodiment of the present invention. FIG. 5A is a perspective view, and FIG. 5B is a cross sectional view. FIG. 5C is an exploded view and illustrates a manufacturing method.

FIGS. 6A and 6B depict an example of a mounting structure for mounting the current sensing resistor according to the fourth embodiment of the present invention onto a substrate.

FIG. 7 is a perspective view illustrating a configuration example of a current sensing resistor according to a fifth embodiment of the present invention.

FIGS. 8A, 8B, 8C, 8D and 8E illustrate a method of manufacturing the current sensing resistor according to the fifth embodiment of the present invention.

FIG. 9 depicts an example of a mounting structure for mounting the current sensing resistor according to the fifth embodiment of the present invention onto a substrate.

FIGS. 10A and 10B are perspective views of a conventional current sensing shunt resistor.

### DESCRIPTION OF EMBODIMENTS

In the following, embodiments of the present invention will be described with reference to the drawings.

### First Embodiment

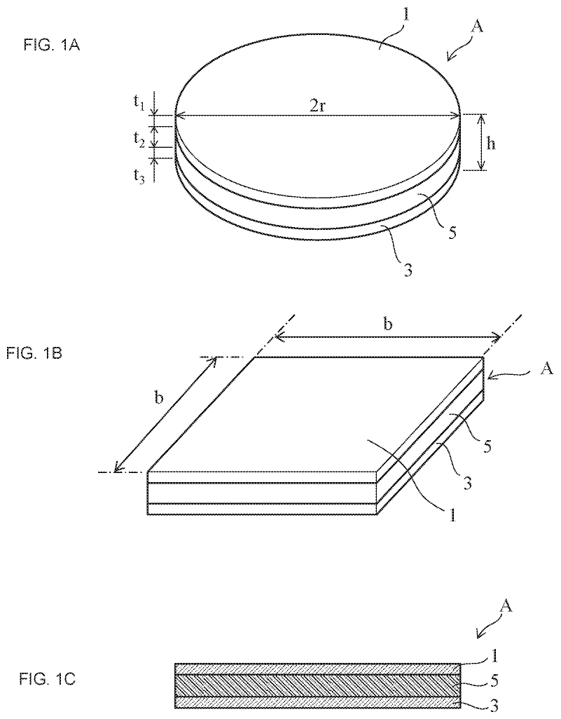

FIGS. 1A, 1B and 1C depict a configuration example of a current sensing resistor according to a first embodiment of the present invention. FIG. 1A is a perspective view, and FIG. 1C is a cross sectional view.

As depicted in FIG. 1A and FIG. 1C, a current sensing shunt resistor A according to the present embodiment is provided with a disc-shaped resistive element 5, and disc-shaped first electrode (terminal) 1 and second electrode (terminal) 3 that are formed on both surfaces of the resistive element 5 to flow current through the resistive element. The resistive element 5 is made from a metal material suitable for sensing current, such as a Cu—Ni based or a Cu—Mn based metal material. The first electrode 1 and the second electrode 3 are made from a highly electrically conductive metal material, such as Cu. The first and second electrodes 1, 3 respectively have thicknesses t1, t3. The resistive element 5 has a thickness t2. Thus, a thin cylindrical laminate having a thickness (height) of h (=t1+t2+t3) is formed. The laminate has a radius r.

The shunt resistor A has an exemplary size as follows.

Electrode: t₁=t₃=0.1 mm

Resistive element: t₂=0.2 mm

Laminate: h=0.4 mm

Laminate: r=1.5 mm

In this case, if the resistive element 5 has a specific resistance value ρ=1 mΩ·cm, the resistance value of the shunt resistor A is 0.3 mΩ. If the thickness t₂ of the resistive element 5 is decreased to 0.1 mm, the overall height h will be 0.3 mm, and the resistance value of the shunt resistor A will be 150μΩ.

Preferably, the size of the shunt resistor A is less than or equal to 5 mm. Concretely, the size herein refers to the diameter 2r of the shunt resistor A in FIG. 1A. In the shunt resistor A depicted in FIG. 1B, the size refers to a side b. If the shunt resistor A has an elliptical or oblong planar shape, for example, the size refers to a maximum width. That is, in the shunt resistor A, the maximum size in width, length, or height (particularly, the width or length of the planar shape) is less than or equal to 5 mm. It may be said that the outer-shape size is less than or equal to 5 mm. Preferably, the shunt resistor A as a laminate has a thickness of less than or equal to 0.5 mm as a whole. Such sizing makes it possible to constitute a shunt resistor that is suitable for mounting on a wiring member, facilitates mounting of a power semiconductor and the like, and is preferable in terms of characteristics. The thicknesses of the first terminal and the second terminal are made smaller than the thickness of the resistive element. This makes it possible to obtain a predetermined resistance value while making the shunt resistor low-profile.

With the structures depicted in FIGS. 1A, 1B and 1C, it is possible to decrease the footprint and also volume of the shunt resistor A. Because the shunt resistor A has a vertical structure, it is possible to ensure level surfaces for the upper and lower surfaces. That is, in the shunt resistor A, the upper surface and/or the lower surface constitute the largest and flat surfaces. Accordingly, mounting becomes stable during connection to wiring members and the like. In addition, a region for wire connection can be preferably ensured. As will be described later, it is possible to mount the shunt resistor A on a component of something, or to mount and use an electronic component and the like on the shunt. Thus, more effective area utilization for the shunt resistor A becomes possible. The first electrode (terminal) and the second electrode (terminal) may have different areas. For example, the upper area may be smaller.

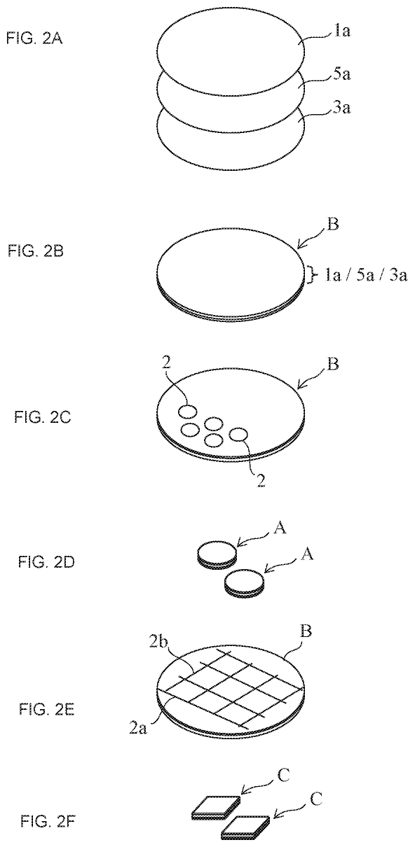

FIGS. 2A to 2D depict an example of a manufacturing process for the shunt resistor according to the present embodiment. First, disc-shaped electrode materials 1a, 3a and a disc-shaped resistive material 5a are prepared. Then, the disc-shaped electrode material 1a, the disc-shaped resistive material 5a, and the disc-shaped electrode material 3a are stacked in this order (FIG. 2A). The materials are surface-bonded to each other by press-bonding, for example, whereby a laminated structure B depicted in FIG. 2B can be formed.

Thereafter, the laminated structure B is punched out into circular shapes using a punch, for example, whereby individual shunt resistors A can be formed (FIG. 2C, and FIG. 2D).

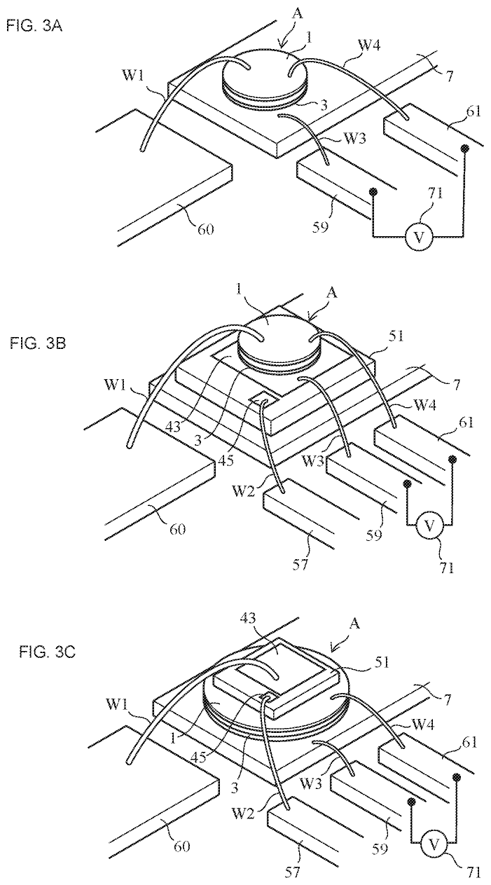

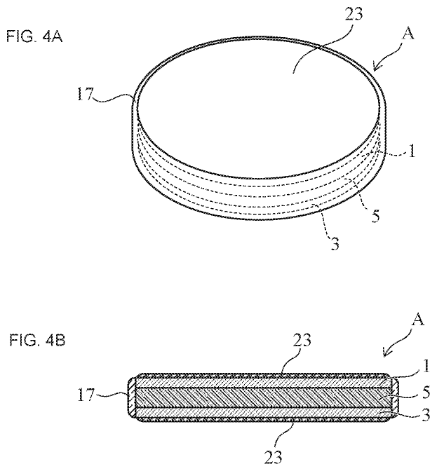

FIG. 3A to FIG. 3C are perspective views illustrating examples of a mounting structure for the shunt resistor A. The shunt resistor A is the structure depicted in FIG. 1A, and the following description will be made with reference to FIG. 1A.

### (First Mounting Structure Example)

FIG. 3A depicts a first mounting structure example for the shunt resistor A, in which the shunt resistor A is disposed on a wiring member 7. The portion of the wiring member 7 in which the shunt resistor A is installed is referred to as a pad. The second electrode 3 of the shunt resistor A is connected to the wiring member 7 (pad).

Wiring members 59, 60, 61 which are separated from the wiring member 7 on which the shunt resistor A is disposed are also provided. The wiring members 7, 59, 60, 61 are plate-like wiring materials made of a copper plate or the like, such as a lead frame. The wiring members may be wiring members of Cu and the like formed on a ceramic substrate or a resin substrate. The same applies to implementation examples which will be described below. The shunt resistor A and the wiring member 7 are connected and fixed by soldering, for example. The first electrode 1 of the shunt resistor A and the wiring member 60 are electrically connected by a bonding wire W1. The first electrode 1 of the shunt resistor A and the wiring member 61 are electrically connected by a bonding wire W4. A part of the wiring member 7 in the vicinity of the mounting portion for the shunt resistor A and the wiring member 59 are electrically connected by a bonding wire W3. The wiring member 7, the shunt resistor A, the bonding wire W1, and the wiring member 60 constitute a current path. In the current path, a voltage drop due to the shunt resistor A is taken by the bonding wires W3, W4. Thus, with the mounting structure depicted in FIG. 3A, it is possible to measure the voltage between the wiring member 59 and the wiring member 61 using a voltmeter 71. With the mounting structure for the shunt resistor A, compared to the structure depicted in FIGS. 10A and 10B, it is possible to reduce stress between the wiring members and the electrodes. In addition, the mounting structure is made smaller than before, making it possible to maintain a good state of connection with respect to heat cycle or the like. The wiring members, the shunt resistor A, and the wires may be sealed with mold resin.

### (Second Mounting Structure Example: Mounting Over Electronic Component)

FIG. 3B depicts a second mounting structure example for the shunt resistor A, in which the shunt resistor A is disposed over an electronic component 51 installed on the wiring member 7. The electronic component 51 is a semiconductor element, such as a power MOS transistor, for example. The shunt resistor A and the electronic component 51 are connected and fixed by soldering, for example. The electronic component 51 has two independent main electrodes. One is a main electrode 43. The other main electrode (not depicted) is formed on the back-surface side of the electronic component 51 so as to oppose the wiring member 7, and is connected with the wiring member 7. Sign 45 designates a terminal for inputting signals to the electronic component 51, for example. The second electrode 3 of the shunt resistor A is connected to the top of the main electrode 43 of the electronic component 51. The bonding wire W1 connects the first electrode 1 with the wiring member 60. The bonding wire W4 connects the first electrode 1 with the wiring member 61. The bonding wire W3 connects the main electrode 43 on which the shunt resistor A is installed with the wiring member 59. The bonding wire W2 connects the signal terminal 45 with a wiring member 57.

In the mounting structure depicted in FIG. 3B, the wiring member 7 and the wiring member 60, with the electronic component 51, the shunt resistor A, and the bonding wire W1 interposed therebetween, constitute a current path. For example, the electronic component 51 controls a current therethrough by a control signal inputted to the signal terminal 45. A voltage drop due to the shunt resistor A is taken by the bonding wires W3, W4 and can be measured by the voltmeter 71 via the wiring member 59 and the wiring member 61. That is, with this mounting structure, it is possible to sense a current flowing through the shunt resistor A in the structure in which the shunt resistor A is connected between the electrode 43 of the electronic component 51 and the wiring member 60 of a substrate. There is also the advantage that the heat generated by the electronic component 51 can be allowed to escape to the wiring side.

### (Third Mounting Structure Example: Mounting Under Electronic Component)

FIG. 3C depicts a third mounting structure for the shunt resistor A, in which the shunt resistor A is disposed on the wiring member 7 formed on an insulating substrate or the like.

Further, the electronic component 51 is disposed over the first electrode 1 of the shunt resistance A. The electronic component 51 has two independent main electrodes. One is a main electrode 43. The other main electrode (not depicted) is formed on the back-surface side of the electronic component 51 and is connected with the first electrode 1. Sign 45 designates a terminal for inputting signals to the electronic component 51, for example. The bonding wire W1 connects the main electrode 43 with the wiring member 60. The bonding wire W4 connects the first electrode 1 with the wiring member 61. The bonding wire W3 connects a part of the wiring member 7 in the vicinity of the mounting portion for the shunt resistor A with the wiring member 59. The bonding wire W2 connects the signal terminal 45 with the wiring member 57.

In this mounting structure, the wiring member 7 and the wiring member 60, with the shunt resistor A, the electronic component 51, and the bonding wire W1 interposed therebetween, constitute a current path. For example, the electronic component 51 controls a current therethrough by a control signal inputted to the signal terminal 45. A voltage drop due to the shunt resistor A is taken by the bonding wires W3, W4. In the structure in which the shunt resistor A is connected between the electrode 43 of the electronic component 51 and the wiring member 7 on the substrate, it is possible to sense the current flowing through the shunt resistor A.

In the example of FIGS. 3B and 3C, in the configuration for sensing a current inputted to the electronic component 51 or a current outputted from the electronic component 51, the apparatus can be made smaller. The structure of the shunt resistor A has small footprint and a small resistive element distance. Accordingly, the self-inductance can be decreased, which is preferable for switching elements, for example.

### Second Embodiment

FIG. 1B is a perspective view illustrating a configuration example of a current sensing resistor according to a second embodiment of the present invention. As depicted, a quadrangular shape may be formed. As depicted in FIG. 2E, after the laminated structure of FIG. 2B has been formed, cutting is performed as illustrated by signs 2a, 2b, whereby quadrangular shunt resistors C depicted in FIG. 2F can be formed. The mounting structure and the like may be similar to those of the first embodiment.

### Third Embodiment

FIG. 4A is a perspective view illustrating a configuration example of a current sensing resistor according to a third embodiment of the present invention. FIG. 4B depicts an example of a cross section taken along a line passing through the center of the circle of FIG. 4A.

In the shunt resistor A according to the present embodiment, a metal thin-film layer of Ni, NiP, NiW, Au or the like is formed on the first electrode 1 and the second electrode 3. The plating method may be electrolytic plating, non-electrolytic plating, or sputtering, for example. By forming such plating film (metal thin-film layer) 23, it becomes possible to obtain an electrode structure that can withstand mounting by high-temperature soldering and a surface treatment for enabling aluminum wire bonding, for example.

As depicted in FIG. 4B, an insulating film (side wall) 17 is formed on the side surface of the resistive element 5 prior to the plating step. In this way, it becomes possible to prevent a short circuit between the first electrode 1 and the second electrode 3 due to the plating film on the side surface. Even when the plating film 23 is not formed, forming the insulating film 17 makes it possible to provide insulation between the first and second electrodes and is therefore preferable. A structure provided with the plating film 23 but not provided with the insulating film 17 may be adopted.

### Fourth Embodiment

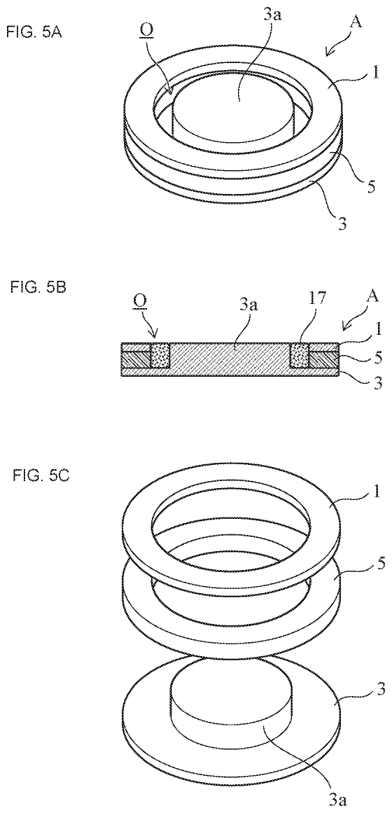

FIG. 5A is a perspective view illustrating a configuration example of a current sensing resistor according to a fourth embodiment of the present invention. FIG. 5B is an example of a cross section taken along a line passing through the center of the circle of FIG. 5A. FIG. 5C is an exploded perspective view.

The shunt resistor A according to the present embodiment includes a first electrode 1 and a resistive element 5 that are ring-shaped and have a through-hole, and a disc-shaped second electrode 3 formed underneath and having a protruding shape. The first electrode 1 and the second electrode 3 have different areas that appear on the outer surfaces of the shunt resistor, the area of the first electrode being smaller than the area of the second electrode. The second electrode 3 includes a protrusion 3a protruding in a space inside the ring-shaped first electrode and resistive element 5. A groove O is formed between the protrusion 3a of the second electrode 3 and the ring-shaped first electrode and resistive element 5. The groove O may be filled with an insulator 17, as depicted in FIG. 5B. For example, as the insulator 17, epoxy resin, cement material, ceramic paste or the like may be filled in the groove O. In another example, a member obtained by processing an insulating material, such as ceramic, into a shape that can be fitted in the groove O may be accommodated in the groove O and fixed by an adhesive, for example.

As depicted in FIG. 5C, a laminated structure of the ring-shaped first electrode 1 and resistive element 5 is formed, and the protrusion 3a of the second electrode 3 is inserted into the space with a gap. Then, the respective members are integrated by press-bonding, for example. Thereafter, the groove O is filled with the insulator 17 as needed.

In the shunt resistor A according to the present embodiment, the first electrode 1 and a part of the second electrode 3 are exposed on the upper surface. Accordingly, it is possible to take voltage only from the upper surface side. The shape insulates (electrically floats) the connecting portion of the second electrode 3 on the lower surface, and ensures a current path from the first electrode 1 on the upper surface only through a bonding wire that is not depicted. Then, a current flow becomes a current that cancels a magnetic flux, making it possible to also cancel the influence of inductance.

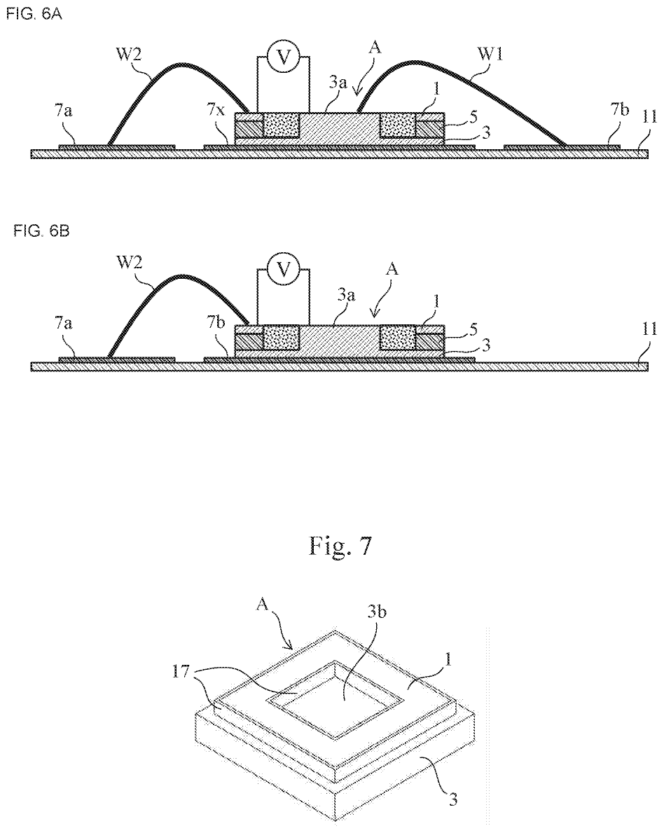

FIG. 6A depicts an example of such mounting structure, illustrating an example of a mounting structure for the current sensing resistor according to the fourth embodiment. As depicted in FIG. 6A, wiring patterns (current line, main path) 7, 7 of Cu are formed on a substrate 11. A pattern 7x is a metal pattern separated from the current path. The second electrode 3 is connected and fixed to the pattern 7x by soldering, for example. The pattern 7x, which is separated from the current path, is provided to fix the second electrode 3 and to promote dissipation of heat from the shunt resistor or electronic component that is installed. The second electrode 3 on the lower surface of the shunt resistor A may be adhered to the substrate without providing the pattern 7x. The wire W2 connects a wiring pattern 7a with the first electrode 1. The wire W1 connects a wiring pattern 7b with the protrusion 3a.

With this configuration, it is possible to cancel a magnetic flux when a current is flowed between the wiring patterns 7a, 7b, as noted above, and to reduce the influence of inductance. In addition, the voltage-sensing wires can be preferably connected to the first electrode 1 and the protrusion 3a (second electrode) on the upper surface side of the shunt resistor A. Accordingly, the upper surface side of the shunt resistor A may be used for sensing voltage, while the lower surface may be used for a heat-dissipating path.

In the configuration of the example depicted in FIG. 6B, the second electrode 3 is connected to the pattern (wiring member) 7b on the substrate 11, while the first electrode 1 is connected with the pattern 7a via the wire W2. In such configuration, when a current is flowed between the wiring patterns 7a, 7b, only the upper surface side may be utilized for sensing voltage.

### Fifth Embodiment

FIG. 7 is a perspective view illustrating a configuration example of a current sensing resistor according to a fifth embodiment of the present invention. The present embodiment is similar to the fourth embodiment in that the first electrode 1 and the resistive element 5 (not depicted in FIG. 7) are ring-shaped. In the present embodiment, the second electrode 3 does not include the protrusion 3a, and constitutes a flat portion 3b. In addition, in the present embodiment, the planar shape is rectangular. Further, in the present embodiment, the insulating material 17 is formed on the inner peripheral portions of the electrode 1 and the resistive element 5 (peripheral wall portions surrounding the flat portion 3b) and on the outer peripheral portions of the electrode 1 and the resistive element 5.

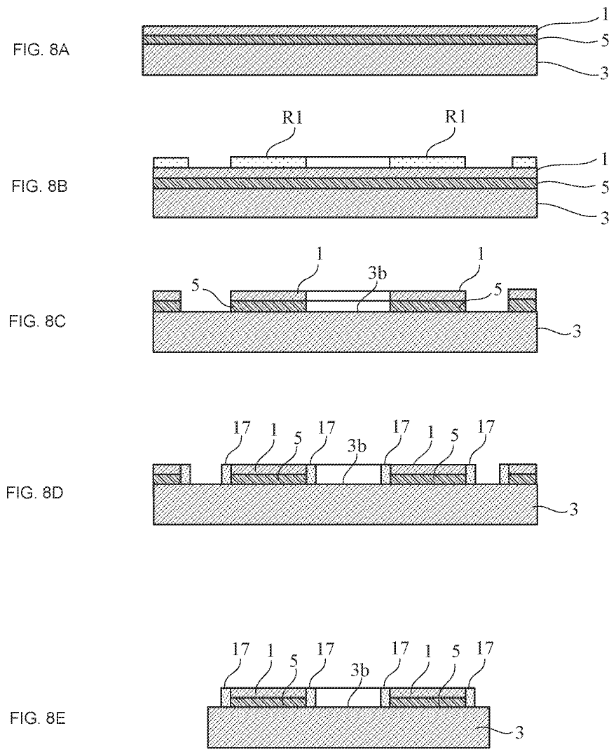

FIGS. 8A-8E illustrate an example of a manufacturing process for the structure of FIG. 7. As depicted in FIG. 8A, a laminate of the first electrode 1, the resistive element 5, and the second electrode 3 is constituted. The second electrode (electrode material) 3 is a copper plate having a predetermined thickness. On the copper plate, the thin film 5 of a resistive material is formed by a thin-film forming method (such as sputtering). Then, the thin film 1 of an electrode material is formed overlapping the resistive material 5. Thus, compared to the thickness of the electrode 3, the resistive material 5 and the electrode material 1 have much smaller thicknesses. The electrode 3 also serves as a base material for holding a plate-like form. Then, as depicted in FIG. 8B, a ring-shaped resist film R1 for patterning the first electrode 1 and the resistive element 5 is formed on top of the first electrode 1. Then, using the resist film R1 as an etching mask, the first electrode 1 and the resistive element 5 are processed into a ring shape by, for example, an ion milling method using Ar. The resist film R1 is removed, whereby the first electrode 1 and the resistive element 5 having a ring shape can be obtained, as depicted in FIG. 8C and FIG. 7.

Then, as depicted in FIG. 8D, after the insulating film 17 of an insulating material, such as SiO₂, is deposited over the whole surface, reactive ion etching (anisotropic etching) is performed using a CHF₃ gas, for example. As a result, the insulating film 17 of SiO₂, for example, remains only on the inner peripheral side surface and the outer peripheral side surface of the rings. In the foregoing, a number of electrodes 1 and resistive elements 5 are formed in a matrix on a large-sized copper plate (electrode) 3, and, as depicted in FIG. 8E, this is cut into a unitary shunt resistor for completion. As needed, a metal thin-film layer may be formed on the surfaces of the electrode 1 and the electrode 3 as described above.

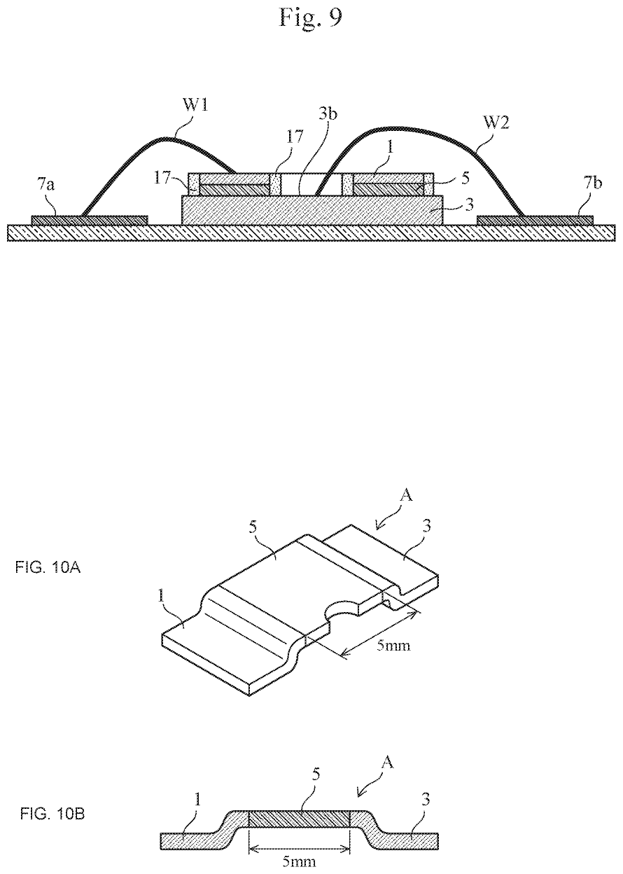

As depicted in FIG. 9, the shunt resistor A is disposed on a substrate provided with the wiring members 7a, 7b. The first electrode 1 and one wiring member 7a are connected by the bonding wire W1. The surface (flat portion 3b) of the second electrode 3 exposed on the inside of the ring and the wiring member 7 are connected by the bonding wire W2.

In this case, because the inner surfaces of the first electrode 1 and the resistive element 5 are covered with the insulating film 17, a short circuit with the bonding wire W2 is less likely to occur. Accordingly, the second electrode 3 and the wiring member 7 can be connected by the bonding wire W2 reliably.

Thus, by using the vertical and thin shunt resistor, the self-inductance can be made extremely low (for example, not more than 0.1 nH). Compared to the length of 5 mm of the conventional resistive element depicted in FIGS. 10A and 10B, the implementation example of the present invention is 0.2 mm, which is approximately 1/25, resulting in a smaller inductance value. Thus, it becomes possible to reduce current sensing error during use at high frequency.

In the foregoing embodiments, the configurations and the like depicted in the attached drawings are not limiting, and may be modified, as appropriate, within the scope in which the effects of the present invention can be obtained. Other various modifications may be made and implemented, as appropriate, without departing from the scope of the purpose of the present invention.

The individual constituent elements of the present invention may be selected as needed, and an invention provided with a selected configuration is also included in the present invention.

### INDUSTRIAL APPLICABILITY

The present invention may be utilized in a current resistor.

All publications, patents, and patent applications cited in the present description are incorporated herein by reference in their entirety

It is therefore intended that the foregoing detailed description be regarded as illustrative rather than limiting, and that it be understood that it is the following claims, including all equivalents, that are intended to define the spirit and scope of this invention.

What is claimed is:

1. A current sensing resistor comprising:
a first terminal and a second terminal which are made from an electrically conductive metal material; and
a resistive element disposed between the first terminal and the second terminal, wherein:
the resistive element, the first terminal, and the second terminal constitute a laminate in a thickness direction; and
the laminate has a size of less than or equal to 5 mm.

2. The current sensing resistor according to claim 1, wherein the laminate has a thickness of less than or equal to 0.5 mm.

3. The current sensing resistor according to claim 1, wherein each of the first terminal and the second terminal has a thickness smaller than a thickness of the resistive element.

4. The current sensing resistor according to claim 1, comprising an insulating material on an outer periphery of the laminate.

5. The current sensing resistor according to claim 1, comprising a metal thin-film layer on a surface of at least one of the first terminal and the second terminal in the thickness direction of the laminate.

6. The current sensing resistor according to claim 1, wherein the first terminal and the second terminal have different areas.

7. The current sensing resistor according to claim 1, wherein the first terminal has a ring shape with a through-hole.

8. A current sensing device comprising:
a semiconductor element having a pair of main electrodes; and
a current sensing resistor disposed on the semiconductor element, and including a first terminal and a second terminal which are made from an electrically conductive metal material, and a resistive element disposed between the first terminal and the second terminal, wherein:
the resistive element, the first terminal, and the second terminal constitute a laminate in a thickness direction; and
the first terminal or the second terminal of the current sensing resistor is connected to at least one of the main electrodes.

9. A current sensing device comprising:
a current sensing resistor including a first terminal and a second terminal which are made from an electrically conductive metal material, and a resistive element disposed between the first terminal and the second terminal, wherein the resistive element, the first terminal, and the second terminal constitute a laminate in a thickness direction, and the laminate has a size of less than or equal to 5 mm; and
a wiring member on which the current sensing resistor is mounted,
wherein the second terminal of the current sensing resistor is connected to the wiring member.

10. The current sensing device according to claim 9, comprising a different wiring member,
wherein the different wiring member and the first terminal are connected by a wire.
